(19) United States
(12) Patent Application Publication
(10) Pub. No.: US 2026/0164594 A1
(43) Pub. Date: Jun. 11, 2026

(54) ELECTRONIC SYSTEM INCLUDING A FORCED CONDITIONED AIR CONVECTION COOLING SYSTEM

(71) Applicant: Aptiv Technologies AG, Schaffhausen (CH)

(72) Inventors: Kesav Kumar Sridharan, Bengaluru (IN); Shrikant Bhadri, Bangalore (IN); Marcin Hyrlicki, Krakow (PL); Krzysztof Adamczyk, Wegrzce Wielkie (PL)

(73) Assignee: Aptiv Technologies AG, Schaffhausen (CH)

(21) Appl. No.: 18/971,891

(22) Filed: Dec. 6, 2024

(51) Int. Cl. H05K 7/20

(52) U.S. Cl. CPC H05K 7/20145; H05K 7/20209

(57) ABSTRACT

An electronic system includes an enclosure including a cooling plenum portion and an electronics system portion. The enclosure includes a base wall, plurality of side walls, and a dividing wall separating the cooling plenum portion and the electronics system portion, the dividing wall including an opening. A circuit board is arranged in the electronics system portion. An electronic chip is mounted to the circuit board. A conditioned air delivery system is arranged to direct a flow of conditioned fluid into the cooling plenum portion. The flow of conditioned fluid passing through the opening into the electronic systems portion to cool the electronic chip.

### FIELD

The present disclosure relates to the art of electronic system and, more particularly, to an electronic system including a forced conditioned air convection cooling system.

### BACKGROUND

This section provides background information related to the present disclosure which is not necessarily prior art.

Electronic devices, when in operation, produce heat. The heat, if left unchecked, can be detrimental to device operation. Elevated temperatures at an interface between an electronic chip and a substrate to which it is mounted can reduce operational efficiency. Manufacturers employ a number of different mechanisms to alleviate the build up of heat in electronics devices. For example, heat sinks may be mounted to heat producing components and air may be directed through the electronic device to convectively cool the heat producing components.

### SUMMARY

This section provides a general summary of the disclosure and is not a comprehensive disclosure of its full scope or all of its features.

An electronic system, in accordance with the present disclosure, includes an enclosure including a cooling plenum portion and an electronics system portion. The enclosure includes a base wall, plurality of side walls, and a dividing wall separating the cooling plenum portion and the electronics system portion, the dividing wall including an opening. A circuit board is arranged in the electronics system portion. An electronic chip is mounted to the circuit board. A conditioned air delivery system is arranged to direct a flow of conditioned fluid into the cooling plenum portion. The flow of conditioned fluid passing through the opening into the electronic systems portion to cool the electronic chip.

In other features, a duct fluidically connects the conditioned air delivery system with the cooling plenum portion.

In other features, the circuit board includes a first circuit board including a first plurality of electronic chips and a second circuit board spaced from the first circuit board, the second circuit board including a second plurality of electronic chips.

In other features, the opening is centered over the electronic system portion.

In other features, a temperature sensor is arranged in the electronic system portion, the temperature sensor detecting a temperature of air in the electronic system portion.

In other features, a board temperature sensor is positioned to detect a board temperature between one or more of the first plurality of electronic chips and the first circuit board.

In other features, a controller is operatively connected to the conditioned air delivery system, the temperature sensor, and the board temperature sensor, the controller being configured to direct the conditioned air delivery system to guide a flow of conditioned fluid through the opening when at least one of the temperature sensor and the board temperature sensor detects a temperature that exceeds a selected temperature value.

In other features, the electronic chip is devoid of a heat sink.

In other features, the plurality of walls is formed from metal.

In other features, the opening is generally rectangular in shape.

A method of cooling an electronic device system includes generating a flow of conditioned fluid, passing the conditioned fluid into a cooling plenum portion of an electronics enclosure; guiding the conditioned fluid through an opening fluidically connecting the cooling plenum portion and an electronic system portion of the electronic enclosure, and delivering the conditioned fluid onto an electronic chip in the electronic system portion of the electronic enclosure.

In other features, passing the conditioned fluid includes passing the conditioned fluid through a duct fluidically connecting a conditioned fluid delivery system with the cooling plenum portion.

In other features, air temperature in the electronic system portion of the electronic enclosure is detected.

In other features, board temperature between the electronic chip and a circuit board is detected.

In other features, the flow of conditioned fluid is generated based on at least one of the air temperature in the cooling plenum portion and the board temperature between the electronic device and the substrate.

In other features, delivering the conditioned fluid through the opening includes directing the conditioned fluid directly onto select portions of the electronic chip.

In other features, delivering the conditioned fluid through the opening includes directing the conditioned fluid indirectly onto other select portions of the electronic chip.

In other features, heated air is passed from the electronic system portion to ambient.

In other features, air in each electronic system portion is replaced after a select time period.

In other features, cooling the electronic device includes reducing a temperature of the electronic chip without using a heat sink.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations and are not intended to limit the scope of the present disclosure.

FIG. 1 is a perspective view of an enclosure including a cooling plenum portion and an electronics system portion connected to a forced conditioned air cooling system, in accordance with the present disclosure;

FIG. 2 is a partial perspective view of the electronics system portion of the electronics system enclosure of FIG. 1 module of the electronic system of FIG. 1, in accordance with the present disclosure;

FIG. 3 is cross-sectional side view of the enclosure of FIG. 1 taken through the lines 3-3, in accordance with the present disclosure;

FIG. 4 is a block diagram illustrating a controller for activating the forced conditioned air cooling system, in accordance with an aspect of the present disclosure; and

FIG. 5 is a flow chart illustrating a method for cooling the electronic system with forced conditioned air, in accordance with the present disclosure.

Corresponding reference numerals indicate corresponding parts throughout the several views of the drawings.

### DETAILED DESCRIPTION

Example embodiments will now be described more fully with reference to the accompanying drawings.

The following description is merely exemplary in nature and is not intended to limit the present disclosure, its application or uses. It should be understood that throughout the drawings, corresponding reference numerals indicate like or corresponding parts and features. As used herein, the term module refers to processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality. In certain aspects, the enclosure may be part of the module.

Adding heat sinks to heat producing components increases system cost and packaging size. Heat sinks, due to the nature of their construction, are costly to produces. Securing a plurality of fins to a substrate takes time and requires material. Forming the substrate to mount or connect with a heat producing component also adds costs. In addition to forming and mounting the heat sink, the package for the heat producing component needs to be sized to accommodate the fins and other structure. Further, a fan must also mount to the package. The fan produces convective air currents that facilitates a heat transfer from the heat sink thereby reducing temperatures of the heat producing component. Thus, using heat sinks to remove heat from heat producing components increases system costs.

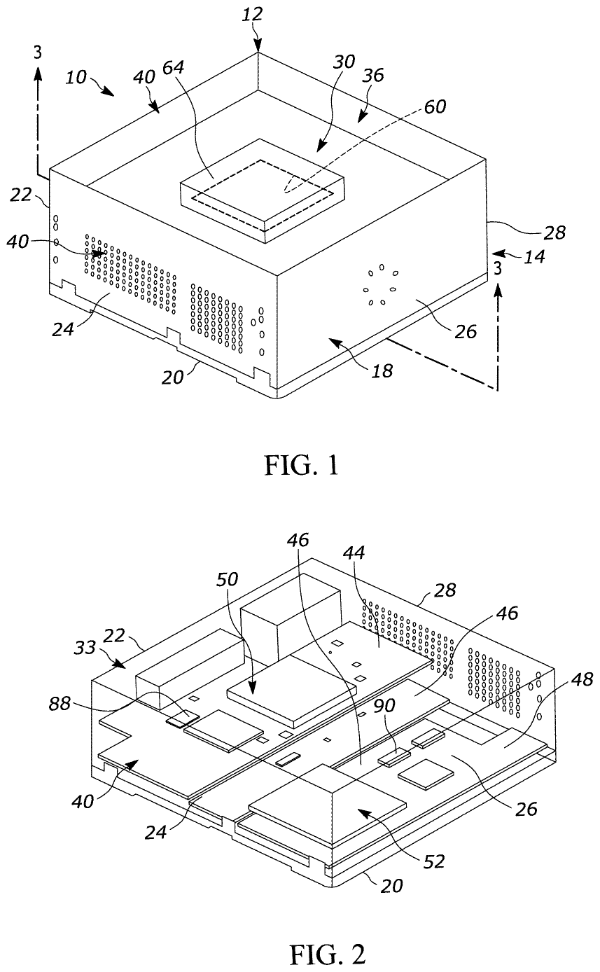

An electronic system, in accordance with the present disclosure, is indicated generally at 10 in FIG. 1. Electronics system 10 is shown in the form of a high performance computing cockpit or cluster (HPCC) 12 that may form part of a vehicle infotainment system (not shown). As such, HPCC 12 may be mounted in a dashboard (also not shown) behind or besides a glove box (not shown). HPCC 12 includes a two-part enclosure 14 formed from a plurality of walls 18. Plurality of walls 18 includes a base wall 20, a first side wall 22, a second side wall 24, a third side wall 26, and a fourth side wall 28. Enclosure 14 also includes a dividing wall 30 spaced from base wall 20 and connected to each of the first side wall 22, second side wall 24, third side wall 26, and fourth side wall 28. Plurality of walls 18 may be formed from aluminum, stamped metal, or other materials.

Enclosure 14 defines an electronics system portion 33 and a cooling plenum portion 36 separated by dividing wall 30. In the non-limiting example shown, second side wall 24 includes a first plurality of openings 40 and fourth side wall 28 includes a second plurality of openings 42 (FIG. 2). First plurality of openings 40 and second plurality of openings 42 fluidically connect electronic systems portion 33 with ambient.

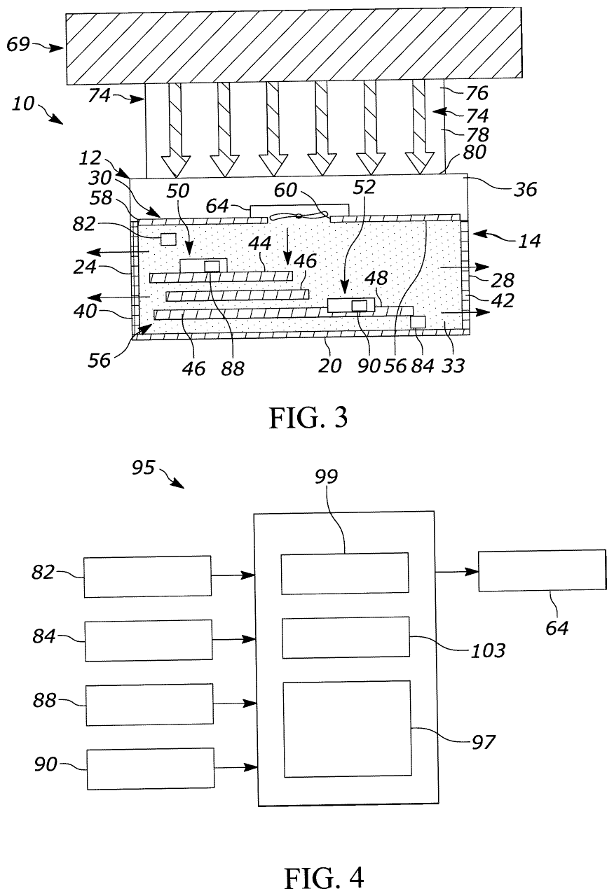

Referring to FIGS. 2 and 3, electronic systems portion 33 houses a first circuit board 44, a second circuit board 46, and a third circuit board 48. Third circuit board 48 may be connected to base wall 20 while first circuit board 44 may be arranged above base wall 20. Second circuit board 46 may be arranged between first circuit board 44 and third circuit board 48. First circuit board 44 may be spaced from base wall 20 and dividing wall 30. First circuit board 44 supports a first plurality of electronic chips 50 and third circuit board 48 supports a second plurality of electronic chips 52. Second circuit board 46 supports additional electronic chips (not separately labeled). Electronic chips 50 and 52 are shown in the form of a system-in-package (SIP) chips 56. It should be understood however that electronic chips 50 and 52 may take on other forms. The number, arrangement, type, and connection of the first plurality of electronic chips 50 on first circuit board 44 and the second plurality of electronic chips 52 on second circuit board 44 may vary. Electronic chips 50 and 52 are also shown to be devoid of a heat sink.

With continues reference to FIG. 3, dividing wall 30 includes an inner surface 56 that forms a top surface (not separately labeled) of electronics system portion 33 and an outer surface 58 that forms a lower surface (also not separately labeled) of cooling plenum portion 36. Dividing wall 30 includes an opening 60 that fluidically connects cooling plenum portion 36 with electronics system portion 33. Opening 60 is centered over electronics system portion 33 and may be rectangular or may possess other geometric forms including circles, ovals, triangles, and the like depending on desired flow characteristics. Further, while shown and described as being centered over electronic system portion 33, the position of opening 60 relative to electronic systems portion 33 may vary.

In accordance with an aspect of the present disclosure, a fan 64 may be supported on outer surface 58 of dividing wall 30 and positioned over opening 60. Fan 64 directs conditioned fluid, such as conditioned or cooled air from cooling plenum 36 into electronics system portion 33. The cooling air flows in a heat exchange relationship with the first plurality of electronic chips 50 and the second plurality of electronic chips 52 and passes from enclosure 14 via first plurality of openings 40 and second plurality of openings 42. While shown and described as including a single fan, it should be understood that depending upon cooling requirements, electronic system 10 may include multiple fans or simply include opening 60.

In accordance with an aspect of the present disclosure, a conditioned air delivery system 69 is fluidically connected to cooling plenum 36. A duct 74 connects conditioned air delivery system 69 to cooling plenum 36. Duct 74 includes an inlet 76 that is configured to receive a flow of conditioned air from conditioned air delivery system 69 and an outlet 78. Duct 74 may take on a variety of form including rigid ducts, flexible ducts, multiple conduits, or perforated openings formed in an outer surface 80 of cooling plenum portion 36.

In accordance with the present disclosure, a number of temperature sensors are arranged about electronics system portion 33. For example, a first temperature sensor 82 may be arranged adjacent to first circuit board 44 and a second temperature sensor 84 may be arranged adjacent to third circuit board 48. In addition, one or more of the first plurality of electronic chips 50 may include a first board temperature sensor 88 and one or more of the second plurality of electronic chips 52 may take the form of a second board temperature sensor 90. Board temperature sensors 88 and 90 are configured to detect a temperature of a connection between corresponding ones of the first electronic chip(s) 50 and first circuit board 44 and the second electronic chip 52 and third circuit board 48.

As shown in FIG. 4, a controller 95 is operatively connected to conditioned air delivery system 69, first temperature sensor 82, second temperature sensor 84, first board temperature sensor 88, and second board temperature sensor 90 and fan 64. Controller 95 includes a central processing unit 97, a temperature sensor module 99, and a non-volatile memory 103. Non-volatile memory 103 may store a set of instructions for controlling conditioned air delivery system 69 and/or fan 64 to cool electronic system portion 33 of enclosure 14. Non-volatile memory 103 may also include temperature set points that determine when cooling is needed and when cooling may not be required. Board temperature should be understood to describe a temperature at an interface between the electronic chips and the correspoinding substrate.

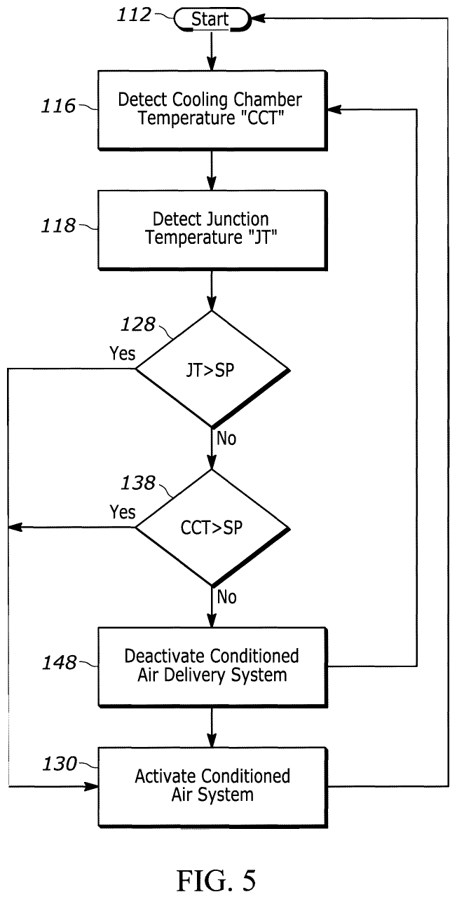

Reference will now follow to FIG. 5 in describing a method of cooling HPCC 12 in accordance with the present disclosure. In block 112, HPCC 12 is activated. In block 116, controller 95 begins to monitor temperatures sensed by first temperature sensor 82 and second temperature sensor 84. In block 118, controller 95 begins monitoring temperatures sensed by first board temperature sensor 88 and second board temperature sensor 90. In block 128, a determination is made whether temperatures sensed by first board temperature sensor 88 and/or second board temperature sensor 90 exceed a board temperature set point stored in non-volatile memory 103. If the temperatures sensed by first board temperature sensor 88 and/or second board temperature sensor 90 exceed the board temperature set point, conditioned air delivery system 69 and fan 64 is activated in block 130.

If the temperatures sensed by first board temperature sensor 88 and/or second board temperature sensor 90 in block 128 are below the set temperature, a determination is made in block 138 whether temperatures sensed by first temperature sensor 82 and second temperature sensor 84 are below a cooling plenum set point stored in non-volatile memory 103. If the temperatures sensed by first temperature sensor 82 and second temperature sensor 84 are above the set point, conditioned air delivery system 69 and fan 64 is activated in block 130. Conditioned fluid may then be directed directly onto select portions of one or more of the first plurality of electronic chips 50 and the second plurality of electronic chips 52 and indirectly onto others of the first plurality of electronic chips 50 and the second plurality of electronic chips 52. If, the temperatures sensed by first temperature sensor 82 and second temperature sensor 84 are below the set point, conditioned air delivery system 69, if active, is deactivated in block 148 and monitoring returns to block 116. Fan 64 may remain active in order to move any remaining conditioned fluid into cooling plenum 33. Further, controller 95 may be programmed to replace a select volume of air in electronic system portion 33 on a periodic basis when HPCC 12 is on operation.

It should be appreciated that cooling planum portion 36 may include a pressure relief valve (not shown) that operates in the event an undesirable pressure increase is detected. Further, divider 30 may include an opening that allows conditioned fluid to pass into electronic systems portion 33 in the event fan 64 fails. Finally, it should be appreciated that depending in individual cooling requirements, each electronic chip 50, 52 may include a dedicated enclosure. For example, electronic chip 50 may include an enclosure (not shown) that is supplied with conditioned fluid from fan 64 and outlet openings that deliver conditioned fluid into a separate enclosure (also not shown) provided about electronic chip 52.

At this point, it should be understood that while described in terms of activating the conditioned air delivery system based on sensed temperature, other operating schemes may also be employed. For example, conditioned air delivery system may be in continuous operation constantly replacing the conditioned fluid in each cooling chamber. In other examples, operation of conditioned air delivery system may be time based. That is, activation of conditioned air delivery system may occur after selected time intervals and for selected time intervals. In all cases, the present disclosure presents a system for cooling electronic devices without using heat sinks. By eliminating the use of heat sinks, packaging requirements may be reimagined, and manufacturing costs reduced. It should however be understood that in certain configurations a heat sink may still be desirable.

Exemplary embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected, or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer, or section. Terms such as “first,” “second,” and other numerical terms when used herein do not imply a sequence or order unless clearly indicated by the context. Thus, a first element, component, region, layer, or section discussed below could be termed a second element, component, region, layer, or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below”, or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terms “substantially” and “about” are intended to include the degree of error associated with measurement of the particular quantity based upon the equipment available at the time of filing the application. For example, “substantially” and/or “about” can include a range of ±8% of a given value.

Unless defined otherwise, technical, and scientific terms used herein have the same meaning as is commonly understood by one of skill in the art to which this disclosure belongs.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. An electronic system comprising:
an enclosure including a cooling plenum portion and an electronics system portion, the enclosure including a base wall, plurality of side walls, and a dividing wall separating the cooling plenum portion and the electronics system portion, the dividing wall including an opening;
a circuit board arranged in the electronics system portion;
an electronic chip mounted to the circuit board; and
a conditioned air delivery system arranged to direct a flow of conditioned fluid into the cooling plenum portion, the flow of conditioned fluid passing through the opening into the electronic systems portion to cool the electronic chip.

2. The electronic system according to claim 1, further comprising a duct fluidically connecting the conditioned air delivery system with the cooling plenum portion.

3. The electronic system according to claim 1, wherein the circuit board includes a first circuit board including a first plurality of electronic chips and a second circuit board spaced from the first circuit board, the second circuit board including a second plurality of electronic chips.

4. The electronic system according to claim 2, wherein the opening is centered over the electronic system portion.

5. The electronic system according to claim 1, further comprising a temperature sensor arranged in the electronic system portion, the temperature sensor detecting a temperature of air in the electronic system portion.

6. The electronic system according to claim 5, further comprising a board temperature sensor positioned to detect a board temperature between one or more of the first plurality of electronic chips and the first circuit board.

7. The electronic system according to claim 6, further comprising a controller operatively connected to the conditioned air delivery system, the temperature sensor, and the board temperature sensor, the controller being configured to direct the conditioned air delivery system to guide a flow of conditioned air through the opening when at least one of the temperature sensor and the board temperature sensor detects a temperature that exceeds a selected temperature value.

8. The electron system according to claim 1, wherein the electronic chip is devoid of a heat sink.

9. The electronic system according to claim 1, wherein the plurality of walls is formed from metal.

10. The electronic system according to claim 1, wherein the opening is generally rectangular in shape.

11. A method of cooling an electronic device system comprising:
generating a flow of conditioned air;
passing the conditioned fluid into a cooling plenum portion of an electronics enclosure;
guiding the conditioned fluid through an opening fluidically connecting the cooling plenum portion and an electronic system portion of the electronic enclosure; and
delivering the conditioned fluid onto an electronic chip in the electronic system portion of the electronic enclosure.

12. The method of claim 11, wherein passing the conditioned fluid includes passing the conditioned fluid through a duct fluidically connecting a conditioned fluid delivery system with the cooling plenum portion.

13. The method of claim 11, further comprising detecting air temperature in the electronic system portion of the electronic enclosure.

14. The method of claim 13, further comprising detecting board temperature between the electronic chip and a circuit board.

15. The method of claim 14, further comprising generating the flow of conditioned fluid based on at least one of the air temperature in the cooling plenum portion and the board temperature between the electronic device and the substrate.

16. The method of claim 11, wherein delivering the conditioned fluid through the opening includes directing the conditioned fluid directly onto select portions of the electronic chip.

17. The method of claim 16, wherein delivering the conditioned fluid through the opening includes directing the conditioned fluid indirectly onto other select portions of the electronic chip.

18. The method of claim 11, further comprising passing heated air from the electronic system portion to ambient.

19. The method of claim 18, further comprising replacing air in each electronic system portion after a select time period.

20. The method of claim 11, wherein cooling the electronic device includes reducing a temperature of the electronic chip without using a heat sink.
